(19) United States
(12) Patent Application Publication
(10) Pub. No.: US 2014/0177188 A1
(43) Pub. Date: Jun. 26, 2014

(54) LASER ENCAPSULATION OF MULTIPLE DISSIMILAR DEVICES ON A SUBSTRATE

(71) Applicant: QUALCOMM MEMS TECHNOLOGIES, INC., San Diego, CA (US)

(72) Inventors: Philip Jason Stephanou, Mountain View, CA (US); Ravindra V. Shenoy, Dublin, CA (US); Kwan-Yu Lai, San Jose, CA (US); James G. Shook, Santa Cruz, CA (US); Nassim Khonsari, Redwood City, CA (US); Peter Jings Lin, Dublin, CA (US); Tsongming Kao, Sunnyvale, CA (US); Peng Cheng Lin, Cupertino, CA (US)

(73) Assignee: QUALCOMM MEMS TECHNOLOGIES, INC., San Diego, CA (US)

(21) Appl. No.: 13/727,124

(22) Filed: Dec. 26, 2012

(51) Int. Cl. B23K 26/20; H05K 7/02

(52) U.S. Cl. CPC B23K 26/20; H05K 7/02
USPC 361/760; 219/121.63; 219/121.64

(57) ABSTRACT

This disclosure provides systems, methods and apparatus for packaging of dissimilar devices using electromagnetic radiation from a laser. In one aspect, an apparatus can include a first substrate, a second substrate, and a first device and a second device disposed on the second substrate. A first metal ring on the first substrate contacts a second metal ring on a second substrate, and is heated by a first electromagnetic radiation from a laser to enclose a first cavity containing the first device. A third metal ring on the first substrate contacts a fourth metal ring on the second substrate, and is heated by a second electromagnetic radiation to enclose a second cavity containing the second device. Enclosing the first cavity may be performed under a first atmosphere, and the enclosing the second cavity may be performed under a second, different atmosphere.

### TECHNICAL FIELD

This disclosure relates to device packaging, and more particularly to substrate to substrate bonding for packaging electromechanical systems and devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

Packaging in EMS devices can protect the functional units of the device from the environment, provide mechanical support for the system components, provide an interface for electrical interconnections, and provide a specified atmosphere necessary for device operation within the package. Substrate to substrate bonding is a technique that may be used in cavity sealing and packaging of EMS devices.

### SUMMARY

The systems, methods and devices of this disclosure each have several innovative aspects, no single one of which is solely responsible for the desirable attributes disclosed herein.

One innovative aspect of the subject matter described in this disclosure can be implemented in a method. The method can include: (a) contacting a first metal ring disposed on a first substrate with a second metal ring disposed on a second substrate; (b) heating the first metal ring and the second metal ring with a first electromagnetic radiation to enclose a first cavity defined by the first metal ring and the second metal ring, the first cavity containing a first device disposed on the first substrate and a first atmosphere; and (c) heating a third metal ring disposed on the first substrate and a fourth metal ring disposed on the second substrate with a second electromagnetic radiation to enclose a second cavity defined by the third metal ring and the fourth metal ring, the second cavity containing a second device disposed on the first substrate and a second atmosphere.

In some implementations, the operation (b) is performed in the first atmosphere. In some implementations, the operation (c) is performed in the second atmosphere. In some implementations, the first atmosphere is different from the second atmosphere. In some implementations, the first electromagnetic radiation impinges on a surface of the second substrate with a path of the first electromagnetic radiation and the surface of the second substrate being substantially perpendicular. In some implementations, heating the first metal ring and the second metal ring includes partially melting the first metal ring and the second metal ring to hermetically seal the first cavity between the first substrate and the second substrate.

Another innovative aspect of the subject matter described in this disclosure can be implemented in an apparatus. The apparatus can include a first substrate; a first device and a second device disposed on the first substrate; and a second substrate, where the first substrate, the second substrate, and a metal ring enclose the first device in a first atmosphere, and the first substrate, the second substrate, and an other metal ring enclose the second device in a second atmosphere different from the first atmosphere.

In some implementations, the first atmosphere includes a vacuum and the second atmosphere includes an inert gas. In some implementations, the metal ring includes a first solder and the other metal ring includes a second solder, where the first solder and the second solder each form hermetic seals. The first solder and the second solder each can include a copper-tin alloy or a gold-tin alloy. In some implementations, the first device includes an actuator device and the second device includes a sensor device.

Another innovative aspect of the subject matter described in this disclosure can be implemented in an apparatus. The apparatus can include a substrate; a first device and a second device disposed on the substrate; a cover; first means for enclosing the first device in a first cavity in a first atmosphere defined by the substrate, the cover, and the first enclosing means; and second means for enclosing the second device in a second cavity in a second atmosphere defined by the substrate, the cover, and the second enclosing means, where the second atmosphere is different from the first atmosphere.

In some implementations, the first atmosphere includes a vacuum and the second atmosphere includes an inert gas. In some implementations, the first enclosing means includes a first solder metal and the second enclosing means includes a second solder metal, wherein the first and the second solder metal each include copper-tin alloy or gold-tin alloy.

Another innovative aspect of the subject matter disclosed in this disclosure can be implemented in an apparatus. The apparatus can include a process chamber. The process chamber can include a chamber wall; a window, where the chamber wall and the window enclose the process chamber to provide a controlled atmosphere inside the process chamber; and a platform for supporting a substrate. The apparatus also can include a laser outside the process chamber and configured to emit electromagnetic radiation through the window into the process chamber.

In some implementations, the platform includes a movable stage configured to move the substrate. In some implementations, the laser is disposed on a movable stage configured to move the laser. In some implementations, the process chamber further includes a plurality of reflective structures configured to redistribute electromagnetic radiation entering from the window through the process chamber. In some implementations, the process chamber further includes a movable reflective structure configured to direct electromagnetic radiation entering from the window through the process chamber. In some implementations, the apparatus further includes a rotatable reflective structure outside the process chamber configured to direct electromagnetic radiation towards the window.

Details of one or more implementations of the subject matter described in this disclosure are set forth in the accompanying drawings and the description below. Although the examples provided in this disclosure may be described in terms of EMS and MEMS-based devices, the concepts provided herein may apply to other types of devices such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 shows an example of a cross-sectional schematic illustration of a metal ring.

FIG. 3A shows an example of a top view schematic illustration of a first substrate with a first metal ring and a third metal ring.

FIG. 3B shows an example of a top view schematic illustration of a second substrate with a second metal ring, a fourth metal ring, a first device, and a second device.

FIG. 4A shows an example of a cross-sectional schematic illustration of a first substrate and a second substrate.

FIG. 4B shows an example of a cross-sectional schematic illustration of a first substrate and a second substrate with a first cavity sealed by a first electromagnetic radiation.

FIG. 4C shows an example of a cross-sectional schematic illustration of a first substrate and a second substrate with a second cavity sealed by a second electromagnetic radiation.

FIG. 5 shows an example of a flow diagram illustrating a manufacturing process for packaging a first device and a second device.

FIG. 6A shows an example of a cross-sectional schematic of an apparatus with a chamber having a movable substrate and housing a plurality of devices to be sealed by a laser.

FIG. 6B shows an example of a cross-sectional schematic of an apparatus with a movable laser and a chamber housing a plurality of devices to be sealed by the laser.

FIG. 6C shows an example of a cross-sectional schematic of an apparatus with a chamber having a plurality of reflective structures and housing a plurality of devices to be sealed by a laser.

FIG. 6D shows an example of a cross-sectional schematic of an apparatus with a chamber having a movable reflective structure and housing a plurality of devices to be sealed by a laser.

FIG. 6E shows an example of a cross-sectional schematic of an apparatus with a chamber housing a plurality of devices to be sealed by a laser having a rotatable reflective structure.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to packaging devices of different types using electromagnetic radiation from a laser. A package can include at least two devices disposed on a substrate with another substrate covering the devices. The substrates can be joined together to form sealed cavities, such as hermetically sealed cavities, in which the devices can be disposed. The atmosphere in each sealed cavity can be different to accommodate the different device types. For example, the atmosphere can have a vacuum, gas, or liquid environment. In other examples, the cavity may not be hermetically sealed and may interact with the ambient environment. In some implementations, the devices can be disposed inside a process chamber with a controlled atmosphere and the devices can be sealed by a laser, where the laser is outside the process chamber.

In some implementations, an apparatus includes first and second substrates, with the first and second devices disposed on the second substrate. A first metal ring on the first substrate contacts a second metal ring on the second substrate, and the first metal ring and the second metal ring are heated by a first electromagnetic radiation to enclose a first cavity containing the first device at a first atmosphere. A third metal ring on the first substrate and a fourth metal ring on the second substrate are heated by a second electromagnetic radiation to enclose a second cavity containing the second device at a second atmosphere.

Particular implementations of the subject matter described in this disclosure can be implemented to realize one or more of the following potential advantages. The use of metal or solder rings to join materials provides high hermeticity and reduced leakage rates, which can improve device reliability. The metal or solder rings improve the mechanical joining reliability of the apparatus, including improvements to yield strength, fracture modulus, and thermal cycling. In addition, a laser delivers localized heat to a desired metal or solder ring so as to avoid applying a uniform temperature and pressure over an entire substrate or panel area. This decouples the dependency of process yield to the level of uniformity of temperature or pressure achieved. This also allows different gases to be provided in different cavities by localized sealing of selected metal or solder rings. Thus, multiple devices of different types that use identical fabrication processes but require different package environments can be sealed without reconfiguring the fabrication processes. Furthermore, localized heat from a laser reduces thermal stress at the substrate or panel level, so that multiple devices of different types can be enclosed on the same substrate at relatively low or room temperature. This also allows for different seal widths and/or different metallurgies on the same substrate that may otherwise require different thermal profiles with other conventional methods.

Of the multiple devices of different types that can be enclosed in the apparatus described herein, some implementations can include an EMS or MEMS device. An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

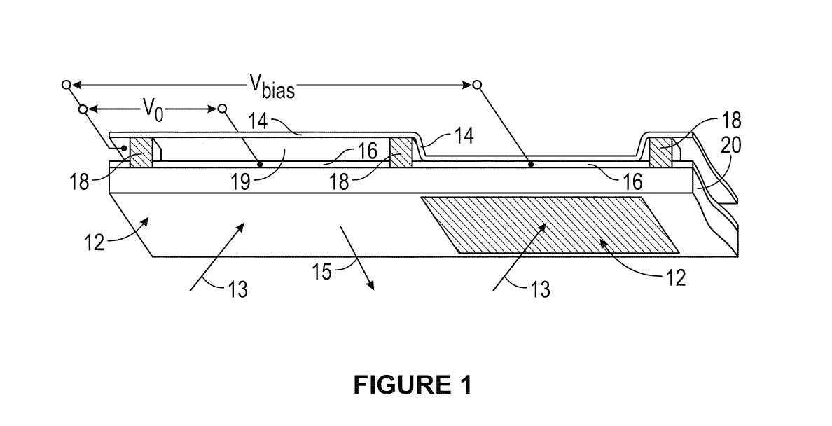

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

IMODs and other EMS devices may be packaged using substrate to substrate bonding. Substrate to substrate bonding can also be used in various other applications, including cavity sealing and packaging of other types of devices. A substrate to substrate bond may be a hermetic seal having a small form factor, a low stress, high reliability, and high uniformity. Further, a substrate to substrate bonding process may have a low thermal budget and a high yield. Achieving all these specifications simultaneously may be challenging with existing thermomechanical bonding of substrates.

Thermomechanical bonding processes typically bond substrates using a low temperature solder metallurgy. This bonding process, however, may have poor yield and the bonds may have poor uniformity and/or low reliability. For example, current solder-based substrate to substrate bonding may be performed with a conventional application of heat and pressure over the entire substrate stack. The maximum allowable temperature of the device or devices may limit the types of solder metallurgies that can be used, which may in turn limit the bond strength and reliability, as well as limiting the yield of the process.

Moreover, substrate to substrate bonding using a polymer based adhesive or an epoxy based adhesive may be non-hermetic or only semi-hermetic, and may include desiccants to be incorporated into the cavity of the package. A polymer based adhesive or an epoxy based adhesive may also need to be cured and set over time in order to reach full bond strength. Furthermore, a polymer based adhesive or an epoxy based adhesive may include a wide seal ring width that increases seal ring form factor, which may otherwise reduce useful device area.

Further, when multiple devices of different types are disposed on the same substrate, the encapsulation specifications for each device may differ. For example, one device may need to be enclosed in a volume having certain atmosphere, and another device may need to be enclosed in a volume having a different atmosphere. An atmosphere may include pressure, gas, liquid, and other environmental conditions. Many existing substrate to substrate bonding techniques, may not allow for different enclosed environments/atmospheres on the same substrate.

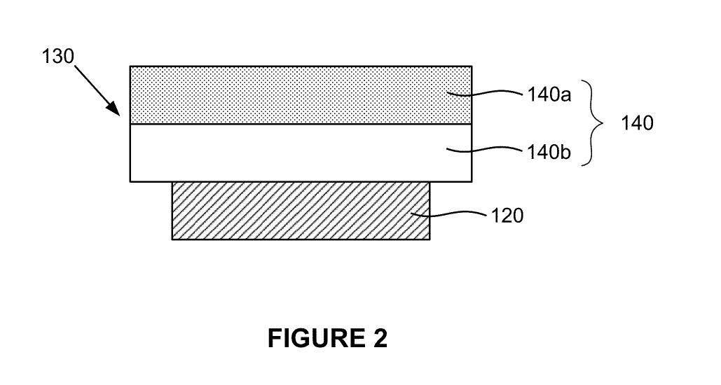

FIG. 2 shows an example of a cross-sectional schematic illustration of a metal ring. In order to achieve high hermeticity, metal, solder, and/or eutectic joining material may be desirable due to the relatively low leakage rates of metal relative to adhesives. In addition, the metal, solder, and/or eutectic joining material may reduce seal ring form factor to increase useful device area. In the example in FIG. 2, the metal ring 130 can include a plurality of layers and/or sub-layers. As illustrated in the example in FIG. 2, the metal ring 130 can include an adhesion layer 140a, a ball limiting layer 140b over the adhesion layer 140a, and a solderable layer 120 over the ball limiting layer 140b. The adhesion layer 140a and the ball limiting layer 140b may form an under bump metal 140.

The adhesion layer 140a may improve adhesion of additional layers to the substrate. In some implementations, for example, the adhesion layer 140a may include but is not limited to titanium (Ti), titanium-tungsten alloy (TiW), and chromium (Cr).

The ball limiting layer 140b may limit the extent of the dissolution of the solderable layer 120 and confine a molten solder metal to the surfaces of the under bump metal 140. The ball limiting layer 140b also may improve the adhesion between the adhesion layer 140a and the solderable layer 120. Without the ball limiting layer 140b, the solderable layer 120 may delaminate from the adhesion layer 140a as the solderable layer 120 is consumed. Moreover, with a ball limiting layer 140b, localized hot spots which consume the solderable layer 120 do not lead to weak delamination spots that may lead to potential reliability problems. The ball limiting layer 140b may include, but is not limited to, a cobalt-chromium (Co—Cr) eutectic and copper-chromium (Cu—Cr) eutectic.

The solderable layer 120 may include an elemental metal or metal alloy solder material that may be joined with another material to form a seal. The solderable layer 120 may be heat activated with a relatively high melting point. For example, the solderable layer 120 may have a melting point of greater than about 200° C. The solderable layer 120 may include alloys of a solder material, such as copper (Cu)/tin (Sn) solder, gold (Au)/Sn solder, Cu/Sn/silver (Ag) solder, Sn/Ag solder, indium (In)/Sn solder, In/Au solder, or another suitable solder. In some implementations, the solderable layer 120 may further include a solder wetting layer (not shown), which may include elemental metals such as Au, Ag, platinum (Pt), and palladium (Pd).

As illustrated in the example in FIG. 2, the width of the solderable layer 120 is less than the width of the under bump metal 140. In some implementations, the width of the solderable layer 120 is between about 100 microns and about a millimeter. The width of the under bump metal 140 is between about 10 microns and about 100 microns greater than the width of the solderable layer 120. The height of the metal ring 130 can be between about 15 microns and about 1 millimeter, such as between about 15 microns and 50 microns. The height of the under bump metal 140 can be between about 0.1 microns and about 5 microns, with the solderable layer 120 making up the remainder of the metal ring 130.

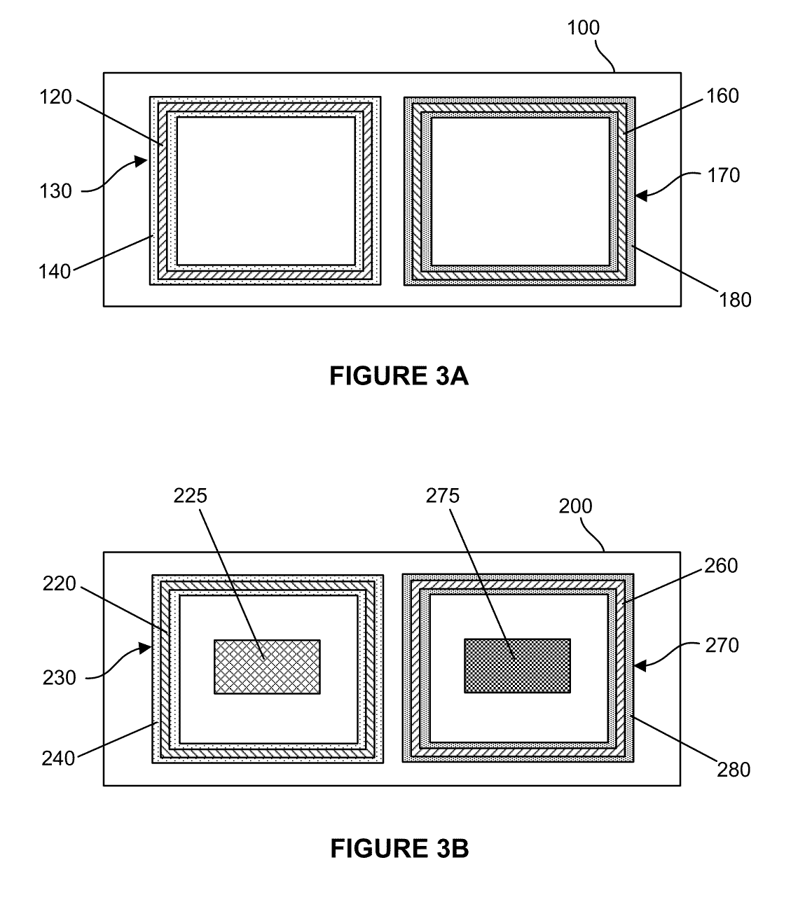

FIG. 3A shows an example of a top view schematic illustration of a first substrate with a first metal ring and a third metal ring. Specifically, it shows the first substrate 100, with first metal ring 130 and third metal ring 170 disposed adjacent to each other on the first substrate 100. FIG. 3B shows an example of a top view schematic illustration of a second substrate with a second metal ring, a fourth metal ring, a first device, and a second device. Specifically, it shows the second metal ring 230 surrounding the first device 225 and the fourth metal ring 270 surrounding the second device 275 on the second substrate 200. Each of the metal rings 130, 170, 230, and 270 may be substantially continuous and disposed along portions of the periphery of the first and second substrates 100 and 200. The metal rings 130, 170, 230, and 270 may each enclose an area between about 100 cm² and about 1 m², such as about 2500 cm², with dimensions between about 10 cm and about 100 cm. The metal rings 130, 170, 230, and 270 may define a sufficient area in which to enclose a first device 225 and a second device 275.

Referring to the examples in FIGS. 3A and 3B, the first substrate 100 and the second substrate 200 can be part of panels with relatively large length and width dimensions, also referred to as the lateral dimensions. For example, tens, hundreds, thousands, millions, or more devices may be fabricated or disposed on a single panel that the first substrate 100 is part of, with a second panel including the second substrate 200 configured to cover these devices. The first and second substrates 100 and 200 may be square or rectangular, or may have other geometries. In some implementations, the lateral dimensions of the first substrate 100 and the second substrate 200 (or larger panels formed in part by the first and second substrates 100 and 200) can be at least 60 cm×80 cm. In some implementations, the lateral dimensions of the first substrate 100 and the second substrate 200 (or larger panels formed in part by the first and second substrates 100 and 200) can be 1 meter or greater. Such relatively large implementations of substrates 100 and 200 may improve scalability to large economies of scale.

The first substrate 100 and the second substrate 200 can each be a generally planar substrate having two substantially parallel surfaces. In various implementations, the first substrate 100 and the second substrate 200 may each be about 100 to about 700 microns thick, about 100 to about 300 microns thick, about 300 to about 500 microns thick, or about 500 microns thick.

In various implementations, the first substrate 100 may be made out of material that is substantially transparent to electromagnetic radiation from a laser. The material of the first substrate 100 may be chosen to be substantially transparent to a range of wavelengths of electromagnetic radiation. For example, when the first substrate 100 includes a glass, the electromagnetic radiation from the laser may be visible radiation or infrared radiation. When the first substrate 100 includes silicon, the electromagnetic radiation from the laser may be infrared radiation.

The first substrate 100 may be, for example, a cover for the first device 225 and the second device 275. The cover of a package can provide protection for the first device 225 and the second device 275 against ambient conditions, such as temperature, pressure, and other environmental conditions. In some implementations, the cover also may include a cover plate, a backplane, a cover glass, a touch panel, a front light, or a display glass.

The second substrate 200 may be made out of any substantially transparent or non-transparent material. In some implementations, the second substrate 200 may be made of the same material as the first substrate 100. In some implementations, the second substrate 200 may be made out of different material from the first substrate 100, and may be opaque to the electromagnetic radiation of a laser.

The second substrate 200 may provide the surface upon which various devices may be built or disposed upon. The second substrate 200 may have a sufficiently large enough area to incorporate multiple devices, including the first device 225 and the second device 275. The first device 225 and the second device 275 may be devices of two different types. For example, the first device 225 and the second device 275 may be part of an IMU having an accelerometer as the first device 225 and a gyroscope as the second device 275. The first device 225 and the second device 275 may include but is not limited to single pixels, displays including an array of IMODs, RF switches, accelerometers, gyroscopes, pressure transducers such as atmospheric pressure sensors, microphones, and microspeakers, gas sensors, displays including an array of MEMS shutters in a digital MEMS shutter (DMS) display, and optical components.

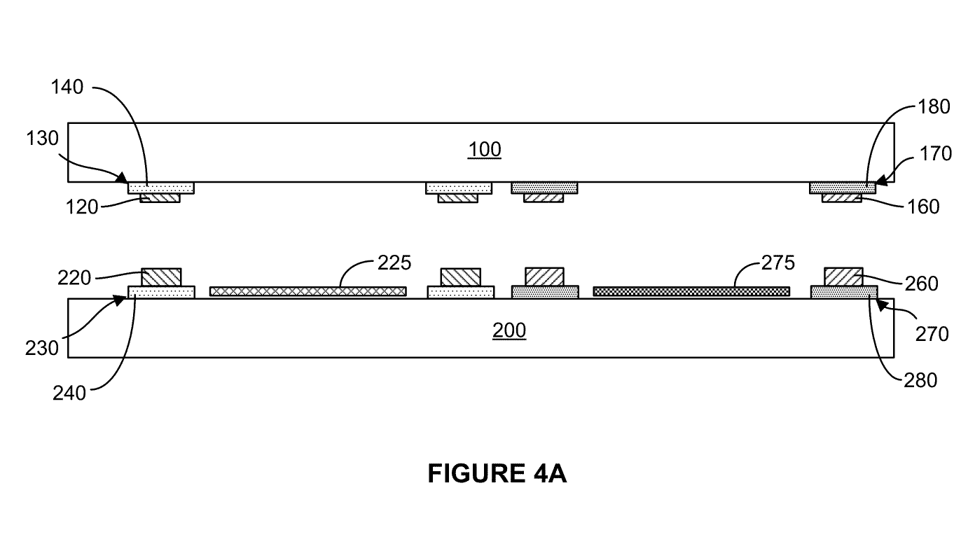

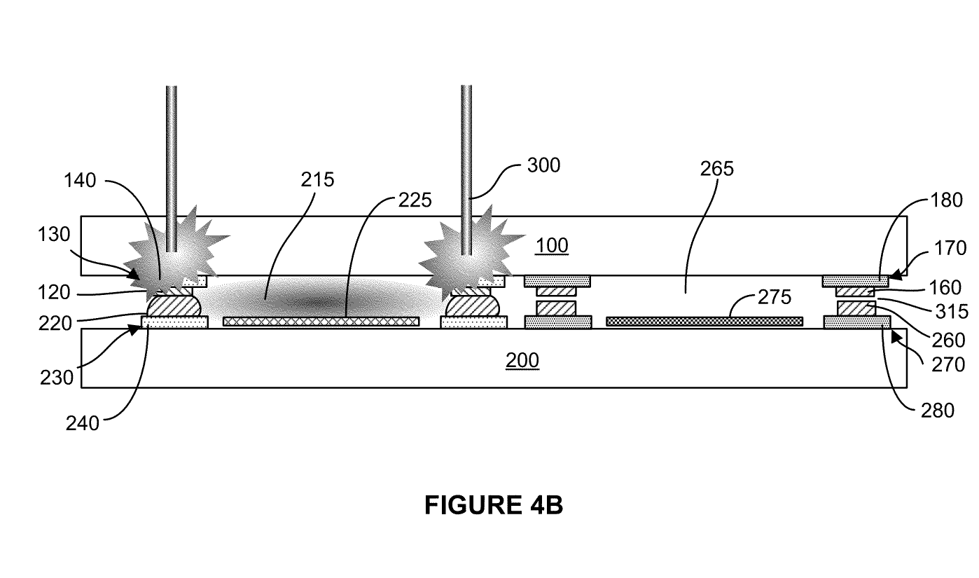

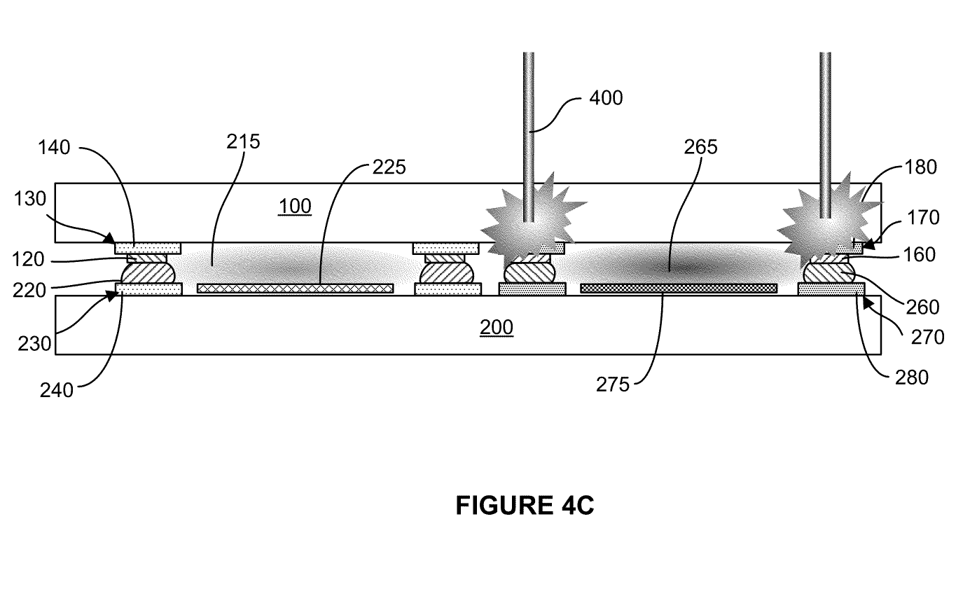

FIGS. 4A-4C show examples of cross-sectional views illustrating various stages of a manufacturing process for packaging a first device and a second device. It is understood that the manufacturing process for packaging the first device and the second device may be applied in the same manner for packaging multiple devices.

FIG. 4A shows an example of a cross-sectional schematic illustration of a first substrate and a second substrate. A first metal ring 130 may be disposed on the first substrate 100 and a third metal ring 170 also may be disposed on the first substrate 100. The first metal ring 130 and the third metal ring 170 may be laterally adjacent to each other. A second metal ring 230 may be disposed on the second substrate 200 and a fourth metal ring 270 may be disposed on the second substrate 200. The second metal ring 230 may be aligned with the first metal ring 130 and the fourth metal ring 270 may be aligned with the third metal ring 170. In addition, a first device 225 and a second device 275 may be disposed over the second substrate 200.

As discussed earlier herein with respect to FIG. 2, each of the metal rings 130, 170, 230, and 270 may include a plurality of layers. For example, the first metal ring 130 may include a first under bump metal 140 and a first solder metal 120, and the second metal ring may include a second under bump metal 240 and a second solder metal 220. Similarly, the third metal ring 170 may include a third under bump metal 180 and a third solder metal 160, and the fourth metal ring 270 may include a fourth under bump metal 280 and a fourth solder metal 260.

Each of the under bump metals 140, 180, 240, and 280 and the solder metals 120, 160, 220, and 260 may be deposited using any suitable deposition technique. For example, in some implementations, the under bump metals 140, 180, 240, and 280 may be seed layers deposited by a combination of sputter deposition and electrodeposition in a manner consistent with semi-additive plating. The process can involve depositing a seed layer, such as a seed layer of Ti/Cu, by sputter deposition, patterning the seed layer by a conventional photolithography technique (for example, depositing photoresist, exposing photoresist, and developing photoresist), and electroplating Cu or Cu followed by Ni and Au. Subsequently, the solder metals 120, 160, 220, and 260 may be deposited by electroplating. Methods other than electroplating may be used, including, for example, electroless plating, evaporation, and sputtering, or a combination thereof. Photoresist may then be stripped using an appropriate method known in the art, and the seed layer may be etched using the electroplated under bump metal or the solder metal layer as a mask.

In some implementations, each of the solder metals 120, 160, 220, and 260 may be substantially elemental metals, such as Cu or Au for the first solder metal 120 and Sn for the second solder metal 220. When the two substantially elemental metals are in contact with one another, the two substantially elemental metals are un-reflowed solder. When the two substantially elemental metals are heated, the metals may reflow or otherwise melt, form a solder metallurgy, and bond the two substrates.

In some implementations, each of the solder metals 120, 160, 220, and 260 may be metal alloys of a solder, including but not limited to Cu-based, Sn-based, Au-based, Ag-based, or indium (In)-based solders, such as a Cu/Sn solder, a Cu/Sn/Ag solder, In/Sn solder, In/Au solder, or an Au/Sn solder. The metal alloys of the solder may form a eutectic joining material that can withstand relatively high processing temperatures. The melting temperatures of such metal alloys may depend at least in part on the chemical composition of the metal alloy, with the chemical composition measured in terms of relative atomic percentages of the elements. For example, an Au/Sn solder may have a melting temperature of about 280° C. with about 80% Au and 20% Sn. In some implementations, the solder metals 120, 160, 220, and 260 may be identical or substantially identical in composition with each other. In some implementations, the solder metals 120, 160, 220, and 260 may be different in composition with each other. For example, the first solder metal 120 may be different from the third solder metal 160, and likewise with the second solder metal 220 and the fourth solder metal 260. Hence, different solder metallurgies may be provided on the same substrate.

FIG. 4B shows an example of a cross-sectional schematic illustration of a first substrate and a second substrate with a first cavity sealed by a first electromagnetic radiation. To enclose the first device 225, the first solder metal 120 and the second solder metal 220 may be brought into contact with each other. The first solder metal 120 and the second solder metal 220 may be heated with a first electromagnetic radiation 300 from a laser. In the illustrated implementation, the first electromagnetic radiation 300 passes through the first substrate 100 before irradiating the first solder metal 120 and the second solder metal 220.

During the enclosing of the first device 225, the atmosphere that the first and second substrates 100 and 200 are in may be an atmosphere needed for the operation of the first device 225. For example, one or more gaps (not shown) may exist between the first solder metal 120 and the second solder metal 220 to allow for gaseous exchange between the soon-to-be-formed first cavity 215 and a chamber in which the bonding is performed. In some implementations, the one or more gaps may be due at least in part to the first solder metal 120 and the second solder metal 220 being un-reflowed. In some implementations, the one or more gaps may be due at least in part to the design constraints of the first solder metal 120 and the second solder metal 220. In other examples, the first solder metal 120 and/or the second solder metal 220 may form discontinuous rings, including rings with one or more notches. The first and second substrates 100 and 200 may be placed in a chamber with a controlled atmosphere having a given gaseous makeup, temperature, and pressure so that the first device 225 is sealed inside the first cavity 215 with the given atmosphere. In some implementations, the controlled atmosphere may include a vacuum so that the chamber is evacuated to remove gases from the first cavity 215.

In some implementations, the first electromagnetic radiation 300 impinges on a surface of the first substrate 100 with the path of the first electromagnetic radiation 300 and the surface of the first substrate 100 being substantially perpendicular. As discussed earlier herein, the first substrate 100 may be substantially transparent to the wavelength of the first electromagnetic radiation 300.

In some implementations, the first electromagnetic radiation 300 at least partially melts the first solder metal 120 and the second solder metal 220 to enclose the first device 225 in a first cavity 215 having a specific atmosphere. In some implementations, the second solder metal 220 may have a high thermal conductivity. The first electromagnetic radiation 300 from the laser may irradiate and heat the second solder metal 220. The second solder metal 220 may conduct heat to the first solder metal 120. In some implementations, the second solder metal 220 may be substantially opaque to the first electromagnetic radiation 300. The solder metals 120 and 220 may reflow or otherwise melt at an interface between the two solder metals 120 and 220.

The partially or fully melted solder metals 120 and 220 may form a hermetic seal that may substantially reduce the ingress of air and water vapor through the seal. The formation of a hermetic seal with joined solder metals 120 and 220 may provide reduced seal ring form factor by maximizing useful device area and reducing costs. In addition, the formation of the hermetic seal may provide increased operational lifetime of the first device 225 by reducing the presence of moisture and other contaminants from entering into the cavity 215 of the first device 225. Further, the formation of the hermetic seal may provide improved mechanical joint reliability by reducing the risk of delamination or breakage.

In some implementations, the first substrate 100 or the first and third under bump metals 140 and 180 may include an optical layer (not shown) to increase absorption of laser energy from electromagnetic radiation. For example, an absorber stack may increase absorption of electromagnetic radiation and decrease reflection of the electromagnetic radiation, more effectively heating the under bump metals and/or subsequent solder metals. The absorber stack may include a dielectric layer, with the thickness of the dielectric layer being about one quarter of a wavelength or peak wavelength of the electromagnetic radiation to increase absorption of the electromagnetic radiation. The absorber stack also may include a metal layer, with a thickness of the metal layer tuned to decrease reflection of the electromagnetic radiation. For example, the dielectric layer may include aluminum nitride (AlN) and the metal layer may include Ti.

The first electromagnetic radiation 300 from a laser may be configured to “write” or move along the entirety of the first metal ring 130 in a predetermined pattern. Laser writing is typically a sequential process as opposed to a batch process. Laser writing can achieve high manufacturing yields by tailoring the write instructions to suit the characteristics across an entire substrate. For example, the laser can tune its power to suit the inherent thickness variations in a given solderable layer from the manufacturing process. Additionally, the heat radiating from the first electromagnetic radiation 300 is relatively localized so as to reduce thermal exposure to and avoid damage to the first device 225. The laser process enables localized heating of each metal ring without adversely impacting electrical routing structures and/or other package components (such as MEMS devices and ICs) that would be otherwise sensitive to high soldering temperatures. Thus, the size of the heating zone is small but the temperature at the solder or metal ring interface is high. A laser beam can have a non-Gaussian, tophat beam profile that enables localized heat transfer. The first electromagnetic radiation 300 can be operated in and around room temperature so as to reduce thermal stresses in the apparatus after bond.

Some types of lasers may include but is not limited to: CO₂ lasers (wavelength of about 10.6 μm), Nd:YAG (wavelength of about 1064 nm, 532 nm, 355 nm), or other appropriate laser source. In some implementations, the laser can have an operating wavelength greater than about 400 nm. Glass is substantially transparent to such operating wavelengths, with optical transmission being greater than about 80% at such operating wavelengths. The laser can provide power levels between about 10 Watts and about 100 Watts to solder the first and second solder metals 120 and 220. Solder metals such as Cu, Ni, and Pt absorb about 30% or more of the energy of visible and infrared laser sources.

Enclosing the first cavity 215 provides a first atmosphere for the operation of the first device 225. After the first device 225 is enclosed in the first cavity 215, there may be a small gap 315 between the third solder metal 160 and the fourth solder metal 260. The gap 315 may be any size sufficient to permit the flow of gas into the second cavity 265. This gap 315 may allow for a different atmosphere for the second device 275 before enclosing the second cavity 265. For example, the first and second substrates 100 and 200 may be placed in a chamber with a controlled atmosphere having a given gaseous makeup, temperature, and pressure so that the second device 275 is sealed inside the second cavity 265 with the given atmosphere. In some implementations, the controlled atmosphere may include a vacuum so that the chamber is evacuated to remove gases from the second cavity 265. The second device 275 may subsequently be enclosed in the second cavity 265.

In some implementations, instead of a gap 315 between the third solder metal 160 and the fourth solder metal 260, the third solder metal 160 and/or the fourth solder metal 260 may form discontinuous rings (not shown), including rings with one or more notches, around the second device 275. A discontinuous ring of the third solder metal 160 and/or the fourth solder metal 260 may allow for the second device 275 to be exposed to the second atmosphere. After gas has flowed into the second cavity 265 and the third solder metal 160 and the fourth solder metal 260 joined, the discontinuous rings also may be closed off to form a seal.

Prior to heating the third solder metal 160 and the fourth solder metal 260 but following heating the first solder metal 120 and the second solder metal 220, the second cavity 265 may be exposed to an ambient environment to provide the second atmosphere within the second cavity 265. In some implementations, exposing the second cavity 265 may include providing a gap between the third solder metal 160 and the fourth solder metal 260. In some implementations, exposing the second cavity 265 includes providing a discontinuous rings for the third solder metal 160 and/or the fourth solder metal 260.

FIG. 4C shows an example of a cross-sectional schematic illustration of a first substrate and a second substrate with a second cavity sealed by a second electromagnetic radiation. The third solder metal 160 and the fourth solder metal 260 may be heated with the second electromagnetic radiation 400 from a laser, with the second electromagnetic radiation 400 passing through the first substrate 100. In some implementations, the third solder metal 160 and the fourth solder metal 260 at least partially melt to enclose the second device 275 in a second cavity 265 having a specific atmosphere.

In some implementations, the second electromagnetic radiation 400 may be different from the first electromagnetic radiation 300. The second electromagnetic radiation 400 may emanate from a different laser having a different wavelength, pulse width, and/or power. Thus, the second electromagnetic radiation 400 may be used for joining different materials, including materials with different melting points, where the first and the second solder metals 120 and 220 may be made of different materials than the third and the fourth solder metals 160 and 260. In some implementations, the second electromagnetic radiation 400 may be identical to the first electromagnetic radiation 300, and may have similar characteristics as the first electromagnetic radiation 300 described earlier herein. In some implementations, the first electromagnetic radiation 300 and the second electromagnetic radiation 400 may emanate from the same laser.

The first cavity 215 may have a first atmosphere and the second cavity 265 may have a second atmosphere, where the first atmosphere is different from the second atmosphere. Hence, upon encapsulation, the first device 225 may be exposed to a pressure, temperature, and liquids/gases different from the second device 275. The first cavity 215 and the second cavity 265 may provide atmospheres necessary for the operations of the first device 225 and the second device 275, respectively.

In some implementations, the first atmosphere may be under vacuum and the second atmosphere may include an inert gas. The different atmospheres may be useful for fabricating inertial measurement units (IMUs) that can acquire motion information for an apparatus such as a navigational apparatus. The IMU can include, for example, gyroscopes and accelerometers. In some implementations, the first device 225 can include an actuator device, such as a gyroscope, with the first cavity 215 having a first atmosphere of vacuum. The second device 275 can include a sensor device, such as an accelerometer, with the second cavity 265 having a second atmosphere including an inert gas. Examples of inert gases include neon or nitrogen, which also can impart viscous damping. The IMU also may include supporting electrodes and interconnects. Each of the cavities can be tuned to a specific pressure and/or filled with specific gases to suit the application of the device in the cavity. For devices that need damping, the cavity in which the device resides can be filled with a suitable gas, such as neon, nitrogen, or argon (Ar). For devices that require vacuum or substantially low pressure, the cavity in which the device resides can be sealed under a suitable pressure or otherwise evacuated. Examples can include an apparatus with an IMOD sealed in an inert gas at about atmospheric pressure and a gyroscope sealed under vacuum. In some implementations, the apparatus can include an accelerometer sealed in an inert gas at about atmospheric pressure.

In some implementations, one of the first device 225 and the second device 275 may be in a liquid filled cavity which may be accomplished by immersing the substrate in a liquid-filled chamber to facilitate filling one of the cavities with liquid. Alternatively, the cavity may be filled with liquid by injecting the liquid prior to laser sealing/soldering. The liquid environment can be used, for example, to add viscous damping, increased electric permittivity or optical index, and/or enhanced heat conduction.

In some implementations, the first device 225 and the second device 275 may include other types of devices, including but not limited to single pixels, displays including an array of IMODs, RF switches, accelerometers, gyroscopes, pressure transducers such as atmospheric pressure sensors, microphones, and microspeakers, gas sensors, DMS displays, and optical components. The apparatus as illustrated in the example in FIG. 4C may provide a completed device package. While the examples in FIGS. 4A-4C illustrate the first device 225 and the second device 275, it is understood that the process may be repeated to produce more than two devices on the same substrate.

The formation of different atmospheres for different device types may be applied to multiple devices in multiple atmospheres. In some implementations, the atmospheres may be hermetic. Thus, the process described earlier herein can be repeated for a third device in a third cavity, a fourth device in a fourth cavity, and so forth. Substrate-level processes, where parts can be processed across substrates containing large numbers of devices (e.g., hundreds, thousands, or millions), can reduce costs by enabling scalability for large economies of scale.

In some implementations, at least one of the cavities may be filled with a dielectric fluid. The cavity may be filled with the dielectric fluid by an injection technique as is known in the art. Examples of devices that may be appropriate in such an atmosphere include DMS displays.

In some implementations, at least one of the cavities may have an atmosphere that is the same or substantially the same as the ambient environment. For example, the metal rings 130, 170, 230, and/or 270 may form non-hermetic seals. Examples of devices that may be suitable in such an atmosphere include gas sensors and pressure transducers, such as atmosphere pressure sensors, microphones, and microspeakers.

Multiple cavities, each cavity with a different atmosphere, including gas, ambient, liquid, or vacuum atmospheres, may provide optimized device performance for each device. Substrate to substrate packaging may further reduce cost that may be scalable to large areas. Moreover, the formation of hermetic seals using laser sealing techniques may further increase device reliability.

In some implementations, the second substrate 200 may include at least one conductive trace (not shown) disposed on the second substrate 200, which may provide an electrical connection to the first device 225 or the second device 275 from the exterior of the first cavity 215 or the second cavity 265 when the first substrate 100 is bonded to the second substrate 200. The region where the conductive trace passes underneath the second under bump metal 240 or the fourth under bump metal 280 may include a high thermal conductivity dielectric layer (for example, AN) between the second under bump metal 240 or fourth under bump metal 280 and the conductive trace. The high thermal conductivity dielectric layer may serve to spread heat from the electromagnetic radiation over a large area. Thus, the high thermal conductivity dielectric layer may dissipate heat away from the conductive trace when the first solder metal 120 and the second solder metal 220 or when the third solder metal 160 and the fourth solder metal 260 are heated with electromagnetic radiation. The high thermal conductivity dielectric layer may reduce the amount of heat conducted to the first device 225 or the second device 275 from the conductive trace when the first solder metal 120 and the second solder metal 220 or the third solder metal 160 and the fourth solder metal 260 are heated with electromagnetic radiation.

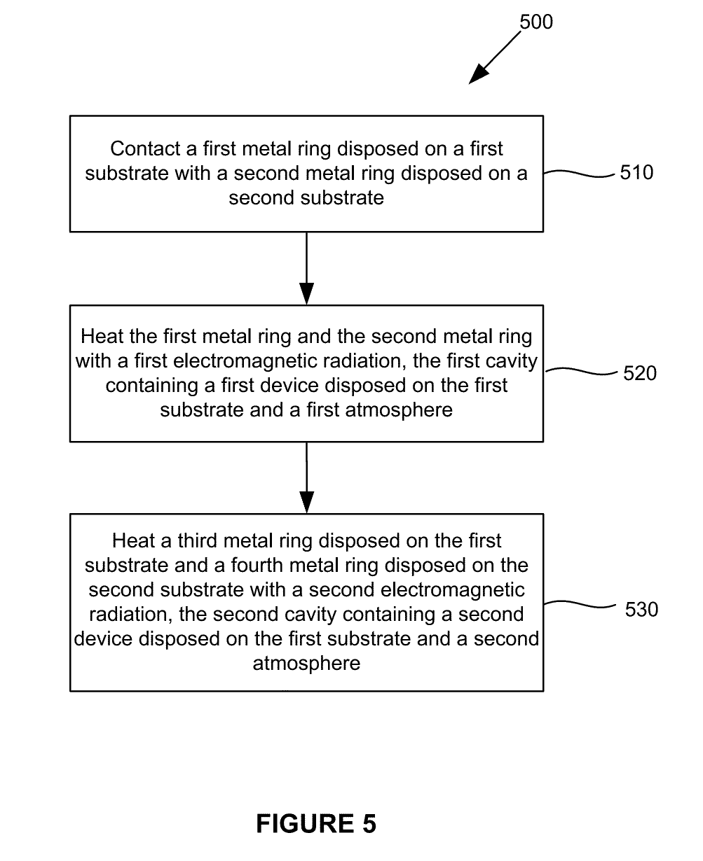

FIG. 5 shows an example of a flow diagram illustrating a manufacturing process for packaging a first device and a second device. It is understood that additional processes not shown in FIG. 5 may be present.

The process 500 begins at block 510, where a first metal ring disposed on a first substrate contacts with a second metal ring disposed on a second substrate. The first metal ring and the second metal ring may each include an under bump metal and a solder metal. The under bump metal may include a plurality of layers, including an adhesion layer and a ball-limiting layer. In some implementations, the first metal ring and the second metal ring may be formed on the substrates using deposition techniques such as electroplating, electroless plating, evaporation, or sputtering, or a combination thereof.

The process 500 continues at block 520 where the first metal ring and the second metal ring are heated with a first electromagnetic radiation to enclose a first cavity defined by the first metal ring and the second metal ring. The first cavity contains a first device disposed on the first substrate and a first atmosphere. Block 520 can be performed in a chamber under the first atmosphere including, for example, gaseous mixture (including vacuum), temperature, and pressure conditions. The first substrate may be substantially transparent to the wavelength of the first electromagnetic radiation. The first electromagnetic radiation may impinge a surface of the first substrate with the path of the first electromagnetic radiation and the surface of the first substrate being substantially perpendicular. In some implementations, prior to enclosing the first cavity, a relatively small gap may be provided between the first metal ring and the second metal ring to allow the flow of gas into the first cavity. In some implementations, prior to enclosing the first cavity, the first metal ring and/or the second metal ring may be discontinuous to allow the flow of gas into the first cavity.

The process 500 continues at block 530 where a third metal ring disposed on the first substrate and a fourth metal ring disposed on the second substrate are heated with a second electromagnetic radiation to enclose a second cavity defined by the third metal ring and the fourth metal ring. The second cavity contains a second device disposed on the first substrate and a second atmosphere. Block 530 can be performed in a chamber under the second atmosphere including, for example, given gaseous mixture (including vacuum), temperature, and pressure conditions. The first substrate may be substantially transparent to the wavelength of the second electromagnetic radiation. The second electromagnetic radiation may impinge a surface of the first substrate with the path of the second electromagnetic radiation and the surface of the first substrate being substantially perpendicular. In some implementations, prior to enclosing the second cavity, a relatively small gap may be provided between the third metal ring and the fourth metal ring to allow the flow of gas into the second cavity. In some implementations, prior to enclosing the second cavity, the third metal ring and/or the fourth metal ring may be discontinuous to allow the flow of gas into the second cavity.

The implementations described earlier herein enable multiple devices of different types to be enclosed on the same substrate at different atmospheres. Prior to enclosing each device, the devices can be disposed on a substrate in a process chamber having a controlled environment. As a result, by controlling the atmosphere of the process chamber, a device can be enclosed in an atmosphere defined by the process chamber, and another device can be subsequently enclosed in a different or same atmosphere defined by the same or a different process chamber.

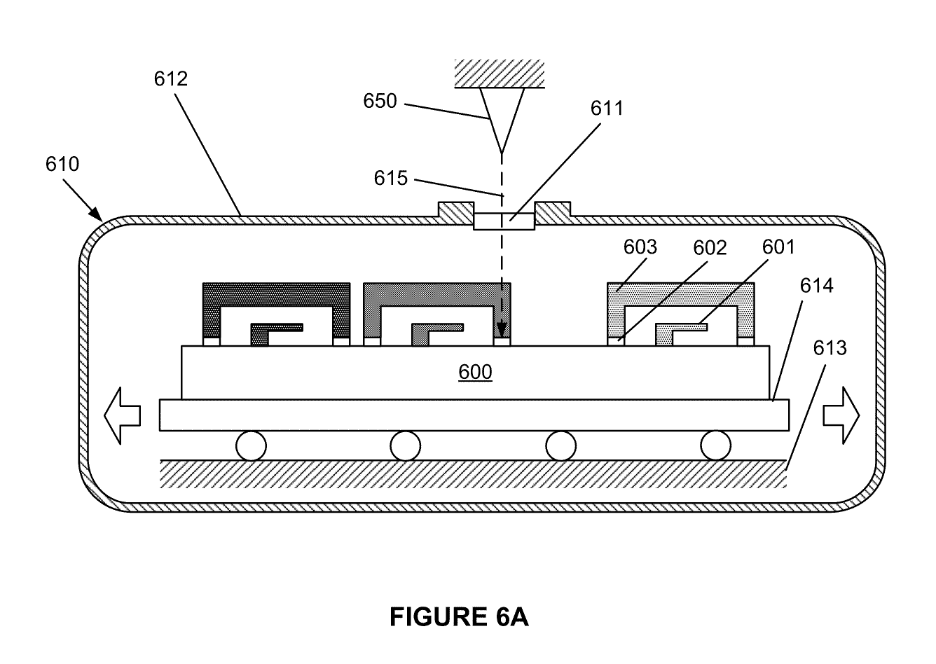

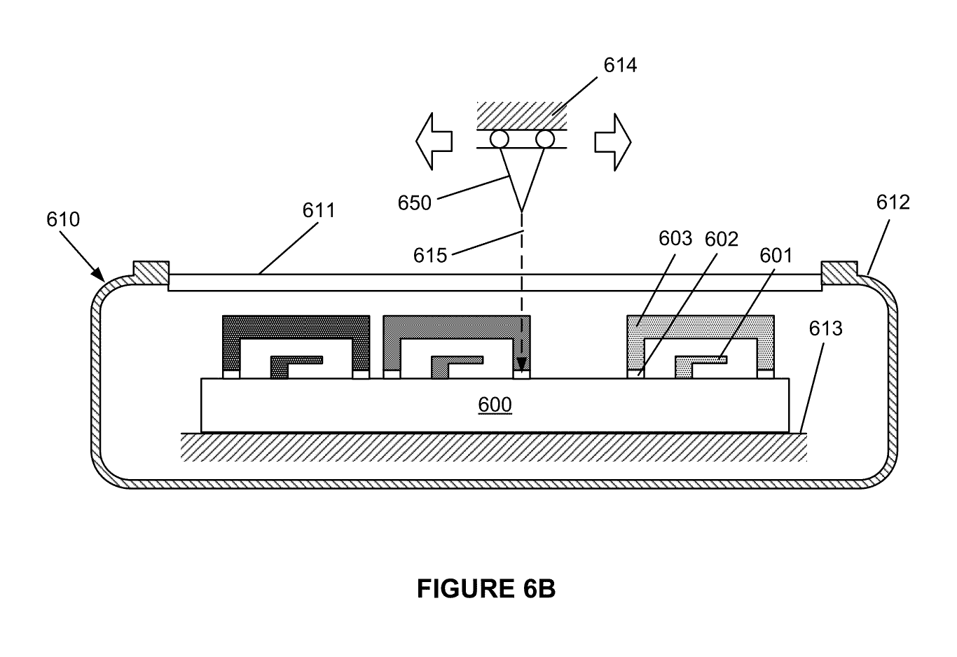

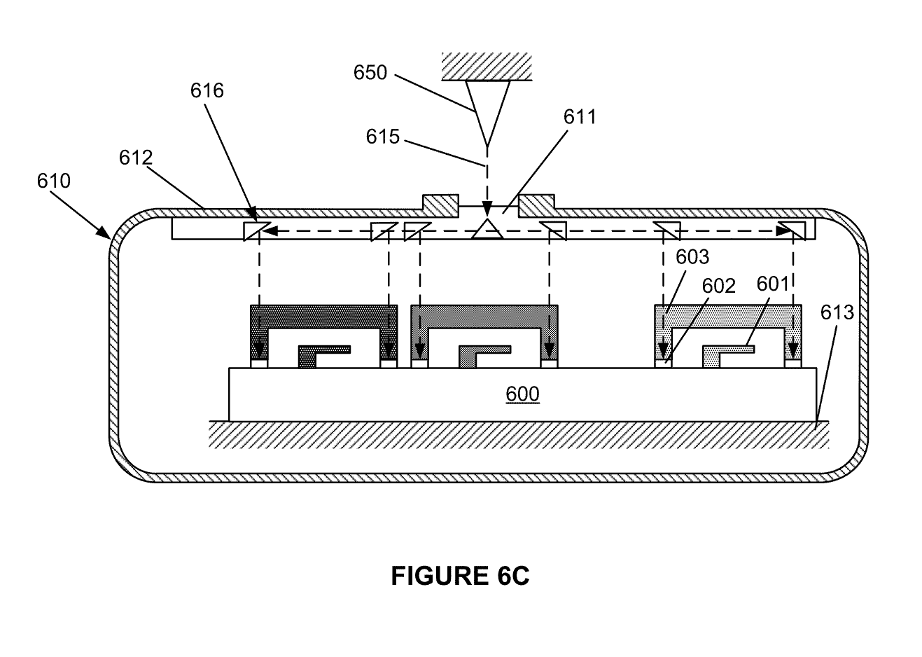

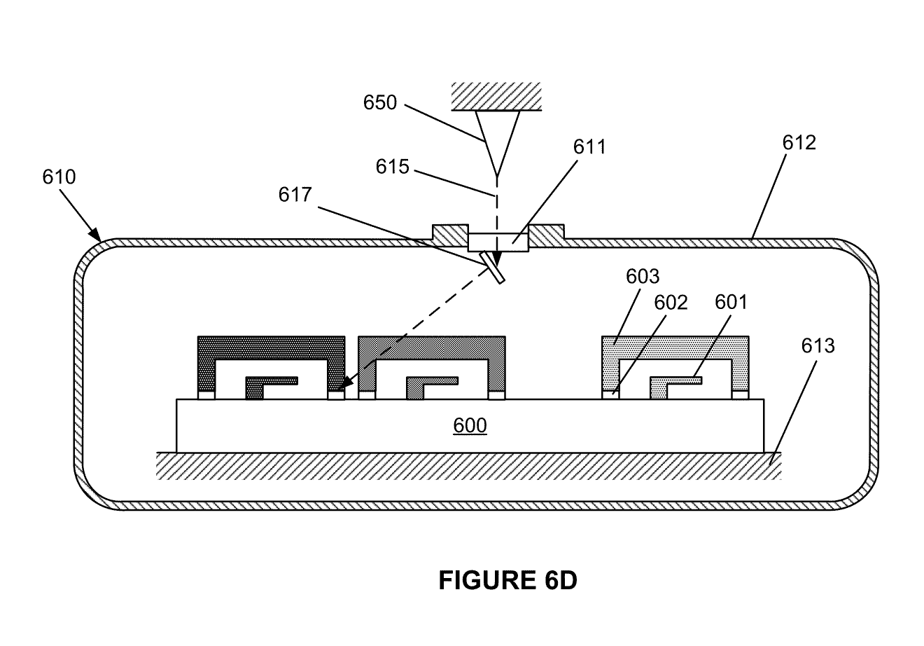

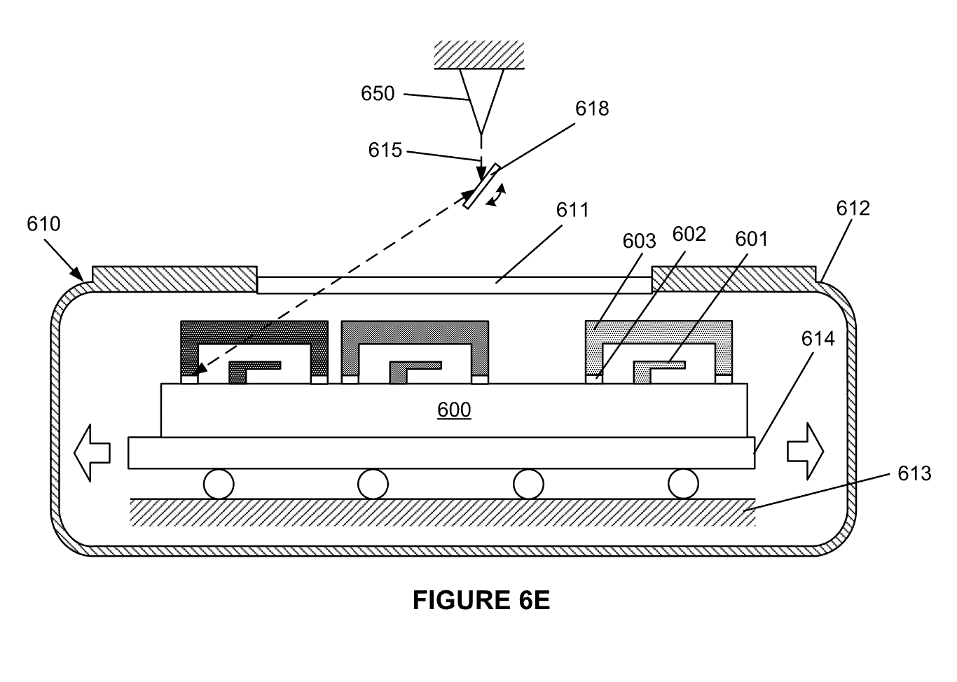

As illustrated in the examples in FIGS. 6A-6E, a process chamber 610 can include a window 611 and a chamber wall 612 such that the window 611 and the chamber wall 612 provide a controlled atmosphere inside the process chamber 610. The process chamber 610 also can include a platform 613 for supporting a substrate. The substrate 600 can have formed thereon a plurality of devices 601 and a plurality of solderable rings 602. One or more covers 603 can be over each device 601 and in contact with each of the solderable rings 602. While the figures show separate covers 603, it is understood that the various covers may be part of a single substrate or alternatively, may be mounted onto a single substrate, for a wafer-level packaging process. A laser 650 outside the process chamber 610 can emit electromagnetic radiation 615 through the window 611 to heat each of the plurality of solderable rings 602 inside the process chamber 610.

FIG. 6A shows an example of a cross-sectional schematic of an apparatus with a chamber having a movable substrate and housing a plurality of devices to be sealed by a laser. The platform 613 in the process chamber 610 can include a movable stage 614 configured to move the substrate 600. The laser 650 may be stationary. In some implementations, the movable stage 614 can have at least two degrees of freedom along a plane that is substantially perpendicular to the path of the electromagnetic radiation 615. Such implementations having a movable substrate and a stationary laser can permit the use of a relatively small window, which can add structural integrity to the process chamber.

FIG. 6B shows an example of a cross-sectional schematic of an apparatus with a movable laser and a chamber housing a plurality of devices to be sealed by the laser. The laser 650 may be disposed on a movable stage 614 that is configured to move the laser 650. The substrate 600 may be stationary. In some implementations, the movable stage 614 can have at least two degrees of freedom along a plane that is substantially perpendicular to the path of the electromagnetic radiation 615. Such implementations having a movable laser and a stationary substrate can permit the use of a relatively small chamber volume, which can reduce potential leaks in the process chamber 610. However, in the implementation of FIG. 6B, the window may need to be larger to allow the movable laser to move and heat solder rings in different devices across the chamber. A larger window can reduce the structural integrity of the process chamber, but such a tradeoff can be useful in implementations where the pressures inside the chamber do not require a strong chamber wall 612 or window 611.

FIG. 6C shows an example of a cross-sectional schematic of an apparatus with a chamber having a plurality of reflective structures and housing a plurality of devices to be sealed by a laser. The process chamber 610 can include a plurality of reflective structures 616 configured to redistribute electromagnetic radiation 615 entering from the window 611 through the process chamber 610. Each of the reflective structures 616 can redirect the electromagnetic radiation 615 to other reflective structures and/or to the solderable rings 602. In some implementations, the reflective structures 616 can be light-turning features, such as facets. The material, size, shape, and quantity of reflective structures 616 can vary. Such implementations having reflective structures can permit the use of a relatively small chamber volume and a relatively small window, which can reduce potential leaks and increase structural integrity of the process chamber 610.

FIG. 6D shows an example of a cross-sectional schematic of an apparatus with a chamber having a movable reflective structure and housing a plurality of devices to be sealed by a laser. The process chamber 610 can include a movable reflective structure 617 configured to direct electromagnetic radiation 615 entering from the window 611 through the process chamber 610. The movable reflective structure 617 can direct electromagnetic radiation 615 to heat the solderable rings 602. In some implementations, the movable reflective structure 617 can be a MEMS mirror having at least two degrees of freedom. In some implementations, the movable reflective structure 617 can be positioned proximate the window 611. In some implementations, the process chamber 610 can have a plurality of windows with a plurality of corresponding reflective structures. Such implementations having reflective structures can permit the use of a relatively small chamber volume and a relatively small window, which can reduce potential leaks and increase structural integrity of the process chamber 610.

FIG. 6E shows an example of a cross-sectional schematic of an apparatus with a chamber housing a plurality of devices to be sealed by a laser having a rotatable reflective structure. The rotatable reflective structure 618 can direct electromagnetic radiation 615 from the laser 650 to heat the solderable rings 602. The laser 650 can be set up with a rotatable reflective structure 618, such as a mirror galvanometer. Implementations of a mirror galvanometer equipped with a static laser can be found in standard industry laser equipment. The mirror galvanometer can provide fast scanning of a laser write path. In some implementations, the process chamber 610 can include a movable stage 614 that is configured to move the substrate 600. Though the mirror galvanometer may provide limited coverage of the substrate 600, the movable stage 614 can enable complete or substantially complete coverage of the substrate 600.

One example process flow for using one of the chambers illustrated in FIGS. 6A-6E may include providing a substrate with a plurality of devices to be sealed by a laser inside the process chamber, for example devices shown in FIGS. 4A-4C or FIGS. 6A-6E. The process continues by providing a first atmosphere inside the pressure chamber. One or more, but not all, devices on the substrate are then sealed using the laser. The process continues by providing an other atmosphere, different from the first atmosphere, in the process chamber. The process continues by sealing one or more not-yet-sealed devices on the substrate using the laser. In this way, a single substrate may be manufactured having multiple packaged devices thereon, such as MEMS devices, with at least one sealed device on the substrate having a first atmosphere and a different sealed device on the substrate having an other given atmosphere that is different from the first.

As used herein, a phrase referring to “at least one of” a list of items refers to any combination of those items, including single members. As an example, “at least one of: a, b, or c” is intended to cover: a, b, c, a-b, a-c, b-c, and a-b-c.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method comprising:
(a) contacting a first metal ring disposed on a first substrate with a second metal ring disposed on a second substrate;
(b) heating the first metal ring and the second metal ring with a first electromagnetic radiation to enclose a first cavity defined by the first metal ring and the second metal ring, the first cavity containing a first device disposed on the first substrate and a first atmosphere; and
(c) heating a third metal ring disposed on the first substrate and a fourth metal ring disposed on the second substrate with a second electromagnetic radiation to enclose a second cavity defined by the third metal ring and the fourth metal ring, the second cavity containing a second device disposed on the first substrate and a second atmosphere.

2. The method of claim 1, wherein operation (b) is performed in the first atmosphere.

3. The method of claim 2, wherein operation (c) is performed in the second atmosphere.

4. The method of claim 1, wherein the first electromagnetic radiation passes through the first substrate before irradiating the first metal ring and the second metal ring.

5. The method of claim 1, wherein the first atmosphere is different from the second atmosphere.

6. The method of claim 5, wherein the first atmosphere includes a vacuum and the second atmosphere includes an inert gas.

7. The method of claim 1, wherein the first electromagnetic radiation impinges on a surface of the second substrate with a path of the first electromagnetic radiation and the surface of the second substrate being substantially perpendicular.

8. The method of claim 1, wherein the first metal ring includes a first under bump metal and a first solder metal, the second metal ring includes a second under bump metal and a second solder metal, the third metal ring includes a third under bump metal and a third solder metal, and the fourth metal ring includes a fourth under bump metal and a fourth solder metal.

9. The method of claim 8, wherein the first, second, third, and fourth solder metals each include at least one of copper, gold, silver, and tin.

10. The method of claim 9, wherein the first, second, third, and fourth solder metals each include copper-tin alloy or gold-tin alloy.

11. The method of claim 1, wherein heating the first metal ring and the second metal ring includes partially melting the first metal ring and the second metal ring to hermetically seal the first cavity between the first substrate to the second substrate.

12. The method of claim 1, further comprising exposing the second cavity to an ambient environment to provide the second atmosphere in the second cavity, wherein exposing the second cavity occurs after heating the first metal ring and the second metal ring but before heating the third metal ring and the fourth metal ring.

13. The method of claim 12, wherein exposing the second cavity includes providing a gap between the third metal ring and the fourth metal ring.

14. The method of claim 12, wherein the third metal ring and/or the fourth metal ring is discontinuous to expose the second cavity.

15. The method of claim 1, wherein the first substrate is substantially transparent to the first electromagnetic radiation and the second electromagnetic radiation.

16. The method of claim 1, wherein the first electromagnetic radiation and the second electromagnetic radiation includes visible radiation or infrared radiation.

17. The method of claim 1, wherein the first device includes an actuator device and the second device includes a sensor device.

18. An apparatus produced by the method as recited in claim 1.

19. An apparatus comprising:
a first substrate;
a first device and a second device disposed on the first substrate; and
a second substrate, wherein
the first substrate, the second substrate, and a metal ring enclose the first device in a first atmosphere, and the first substrate, the second substrate, and an other metal ring enclose the second device in a second atmosphere different from the first atmosphere.

20. The apparatus of claim 19, wherein the first atmosphere includes a vacuum and the second atmosphere includes an inert gas.

21. The apparatus of claim 19, wherein the metal ring includes a first solder and the other metal ring includes a second solder, wherein the first solder and the second solder each form hermetic seals.

22. The apparatus of claim 21, wherein the first solder and the second solder each include copper-tin alloy or gold-tin alloy.

23. The apparatus of claim 19, wherein the second substrate is substantially transparent to infrared radiation.

24. The apparatus of claim 19, wherein the first device includes an actuator device and the second device includes a sensor device.

25. An apparatus comprising:
a substrate;
a first device and a second device disposed on the substrate;
a cover;
first means for enclosing the first device in a first cavity in a first atmosphere defined by the substrate, the cover, and the first enclosing means; and
second means for enclosing the second device in a second cavity in a second atmosphere defined by the substrate, the cover, and the second enclosing means, wherein the second atmosphere is different from the first atmosphere.

26. The apparatus of claim 25, wherein the first atmosphere includes a vacuum and the second atmosphere includes an inert gas.

27. The apparatus of claim 25, wherein the first enclosing means includes a first solder metal and the second enclosing means includes a second solder metal, wherein the first and the second solder metal each include copper-tin alloy or gold-tin alloy.

28. An apparatus comprising:
a process chamber including:
a chamber wall;
a window, wherein the chamber wall and the window enclose the process chamber to provide a controlled atmosphere inside the process chamber; and
a platform for supporting a substrate; and
a laser outside the process chamber and configured to emit electromagnetic radiation through the window into the process chamber.

29. The apparatus of claim 28, wherein the platform includes a movable stage configured to move the substrate.

30. The apparatus of claim 28, wherein the laser is disposed on a movable stage configured to move the laser.

31. The apparatus of claim 28, wherein the process chamber further includes a plurality of reflective structures configured to redistribute electromagnetic radiation entering from the window through the process chamber.

32. The apparatus of claim 28, wherein the process chamber further includes a movable reflective structure configured to direct electromagnetic radiation entering from the window through the process chamber.

33. The apparatus of claim 28, further comprising a rotatable reflective structure outside the process chamber and configured to direct electromagnetic radiation towards the window.
